(19) United States
(12) Patent Application Publication
(10) Pub. No.: US 2010/0245633 A1
(43) Pub. Date: Sep. 30, 2010

(54) SOLID-STATE IMAGE ELEMENT AND SOLID-STATE IMAGE DEVICE

(75) Inventor: Masaki Hanada, Osaka (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/749,749

(22) Filed: Mar. 30, 2010

(30) Foreign Application Priority Data
Mar. 30, 2009 (JP) 2009-080760

(51) Int. Cl. H04N 5/335; H04N 5/217

(52) U.S. Cl. 348/246; 348/311; 348/E05.091; 348/E05.079

(57) ABSTRACT

A solid-state image device has a pixel region in which a plurality of unit pixels 306 are two-dimensionally arranged in the horizontal and vertical directions, the unit pixel 306 being made up of a PD 304 and a VCCD 305, wherein a substrate potential setting pixel 307 is formed in the formation part of the PD 304 of at least one of the unit pixels 306 in a pixel region 301. The substrate potential setting pixel 307 and a substrate potential setting electrode 309 provided outside the pixel region 301 are connected to each other via a low-resistance connection electrode 308. Thus it is possible to suppress a potential difference between high-concentration P-type impurity regions in the pixel region, thereby obtaining a high-quality image with no shading while achieving uniformity over the image.

### FIELD OF THE INVENTION

The present invention relates to a solid-state image element in which photoelectric conversion regions having high-concentration impurity regions are two-dimensionally arranged, and a solid-state image device.

### BACKGROUND OF THE INVENTION

In recent years, CCD image sensors (hereinafter called CCDs) representing solid-state image elements used for rapidly prevailing digital still cameras have been required to have more pixels, higher performance, and smaller sizes. Particularly, an increase in the number of pixels has been highly demanded in the market and thus smaller cells have been required for CCDs.

Referring to FIGS. 8 and 9, a typical CCD used for a digital still camera will be described below.

FIG. 8 is a schematic plan view showing the configuration of a solid-state image element of the prior art. FIG. 9 is a schematic sectional view showing the configuration of the solid-state image element of the prior art.

In FIG. 8, a unit pixel 106 of the CCD is made up of a photoelectric conversion region (also called a photo-diode (PD)) 104 in which incident light is converted into signal charge and the signal charge is stored, and a vertical transfer register (hereinafter also called a VCCD) 105 for reading the signal charge stored in the PD 104 and transferring the signal charge. The unit pixels 106 are two-dimensionally arranged in the vertical and horizontal directions and form a pixel region 101. The signal charge read from the photoelectric conversion region 104 is transferred to a charge-to-voltage conversion part (FDA: floating diffusion amplifier) 103 through the VCCD 105 and a horizontal transfer register (HCCD) 102 and is converted into an output signal voltage.

FIG. 9 is an A-A′ sectional view showing the configuration of the unit pixel 106 in the CCD of FIG. 8.

As shown in FIG. 9, a PD 201 is made up of a high-concentration P-type impurity region 203 provided in the surface layer of a semiconductor substrate 202, and an N-type impurity region 211 provided under the high-concentration P-type impurity region 203. The high-concentration P-type impurity regions 203 are connected to one another in the column direction and have ends grounded outside the pixel region 101, so that the potentials of the high-concentration P-type impurity regions 203 are stabilized. In the row direction, the potential is kept constant through a reading part 205 and the surface of the semiconductor substrate 202. Light incident on the PD 201 generates electron-hole pairs. The holes of the pairs are discharged to GND provided outside the pixel region 101, through the high-concentration P-type impurity region 203. The electrons of the pairs are stored as signal charge in the PD 201.

A vertical charge transfer region 204 is provided on one side of the PD 201 via the reading part 205. By controlling the gate potential of the reading part 205, the signal charge stored in the PD 201 can be transferred to the vertical charge transfer region 204. Formed on the other side of the PD 201 is an element isolation part 206 that prevents the signal charge from leaking to the adjacent pixel.

On the semiconductor substrate 202, a transfer electrode 207 is formed via an insulating film 208 so as to correspond to the top region of the vertical charge transfer region 204. The transfer electrode 207 constitutes a VCCD 209 (the same as the VCCD 105 of FIG. 8). The VCCD 209 is covered with a light-shielding film 210 that prevents incident light from entering the vertical charge transfer region 204.

Since cells have been rapidly reduced in size in recent years, the PD 201 and the VCCD 209 have been reduced in area, accordingly. The area reduction of the PD leads to a reduction in the area of the high-concentration P-type impurity region 203 in each pixel. As has been discussed, the high-concentration P-type impurity region 203 is used as a path for discharging holes generated in the PD 201 to the GND provided outside the pixel region 101, so that smaller cells may increase a resistance in the hole discharge path made up of the high-concentration P-type impurity region 203. Since the high-concentration P-type impurity regions 203 are connected in the column direction and are grounded only outside the pixel region 101, the potentials of the high-concentration P-type impurity regions 203 are unstable at locations away from the ground, for example, the center of the pixel region 101. For this reason, in the configuration where holes generated in the PD 201 are discharged to a contact away from the PD 201 through the high-concentration P-type impurity region 203, a potential difference occurs between the high-concentration P-type impurity region 203 and the GND according to a distance from the GND. The potential difference causes shading (inclination of the overall output image level) and degrades image quality.

### DISCLOSURE OF THE INVENTION

The present invention has been devised in view of image quality degraded by shading that is caused by a resistance increased in a high-concentration P-type impurity region as cells are reduced in size. An object of the present invention is to provide a solid-state image device that can achieve high image quality without increasing manufacturing steps or causing shading, even when cells are reduced in size.

In order to attain the object, a solid-state image element of the present invention is a solid-state image element for vertically and horizontally transferring a charge signal photoelectrically converted in each pixel, the solid-state image element including: a vertical transfer register for vertically transferring the charge signal in response to a control signal inputted to a first transfer electrode; a horizontal transfer register for horizontally transferring the charge signal in response to a control signal inputted to a second transfer electrode; a plurality of first light-shielding films formed at least on the vertical transfer register; at least one substrate potential setting pixel region having a high-concentration impurity region at least in the surface layer of the substrate potential setting pixel region; a substrate potential setting electrode fixed at a ground potential; a connection electrode for connecting the high-concentration impurity region of the substrate potential setting pixel region and the substrate potential setting electrode; and photoelectric conversion regions two-dimensionally arranged in regions other than the substrate potential setting pixel region so as to be adjacent to the vertical transfer register via the first transfer electrode, the photoelectric conversion region being made up of a high-concentration impurity region and an impurity region for storing signal charge.

Further, the substrate potential setting pixel regions may be formed in at least one column.

Moreover, the connection electrode may be connected to all of the substrate potential setting pixel regions of the column.

Further, the connection electrode may be the same film as the first light-shielding film.

Moreover, it is preferable that the high-concentration impurity region formed in the substrate potential setting pixel region is deeper than the high-concentration impurity region formed in the photoelectric conversion region.

Further, it is preferable that the first transfer electrode in a region adjacent to the substrate potential setting pixel region is smaller in width than the first transfer electrode in a region adjacent to the photoelectric conversion region and the second transfer electrode in a region adjacent to the substrate potential setting pixel region is smaller in width than the second transfer electrode in a region adjacent to the photoelectric conversion region.

Moreover, it is preferable that the substrate potential setting pixel region is provided at least around the center of the solid-state image element.

Further, it is preferable that the substrate potential setting pixel region is provided at least between the center of the solid-state image element and the horizontal charge transfer register.

Moreover, the first light-shielding film may be extended to serve as the connection electrode.

A solid-state image element having a shunt wiring structure for vertically and horizontally transferring a charge signal photoelectrically converted in each pixel, the solid-state image element including: a vertical transfer register for vertically transferring the charge signal in response to a control signal inputted to a first transfer electrode; a horizontal transfer register for horizontally transferring the charge signal in response to a control signal inputted to a second transfer electrode; a plurality of first light-shielding films formed at least on the vertical transfer register; a substrate potential setting electrode fixed at a ground potential; a plurality of second light-shielding films horizontally formed in stripes and connected to the substrate potential setting electrode; at least one substrate potential setting pixel region having a high-concentration impurity region at least in the surface layer of the substrate potential setting pixel region; a connection electrode for connecting the high-concentration impurity region of the substrate potential setting pixel region and the second light-shielding film; and photoelectric conversion regions two-dimensionally arranged in regions other than the substrate potential setting pixel region so as to be adjacent to the vertical transfer register via the first transfer electrode, the photoelectric conversion region being made up of a high-concentration impurity region and an impurity region for storing signal charge.

Further, the second light-shielding films may be formed in a lattice pattern also on the first light-shielding films.

Moreover, the connection electrode may be the same film as the second light-shielding film.

A solid-state image device of the present invention preferably includes the solid-state image element and a signal processing circuit for compensating for a missing pixel in the substrate potential setting pixel region.

### BRIEF DESCRIPTION OF THE DRAWINGS

FIG. 1 is a schematic plan view showing the configuration of a solid-state image element according to a first embodiment;

FIG. 2A is a process sectional view showing the manufacturing process of the solid-state image element according to the first embodiment;

FIG. 2B is a process sectional view showing the manufacturing process of the solid-state image element according to the first embodiment;

FIG. 2C is a process sectional view showing the manufacturing process of the solid-state image element according to the first embodiment;

FIG. 2D is a process sectional view showing the manufacturing process of the solid-state image element according to the first embodiment;

FIG. 2E is a process sectional view showing the manufacturing process of the solid-state image element according to the first embodiment;

FIG. 2F is a process sectional view showing the manufacturing process of the solid-state image element according to the first embodiment;

FIG. 3A is a process sectional view showing the manufacturing process of the solid-state image element according to the first embodiment;

FIG. 3B is a process sectional view showing the manufacturing process of the solid-state image element according to the first embodiment;

FIG. 3C is a process sectional view showing the manufacturing process of the solid-state image element according to the first embodiment;

FIG. 3D is a process sectional view showing the manufacturing process of the solid-state image element according to the first embodiment;

FIG. 3E is a process sectional view showing the manufacturing process of the solid-state image element according to the first embodiment;

FIG. 3F is a process sectional view showing the manufacturing process of the solid-state image element according to the first embodiment;

FIG. 4A is a process sectional view showing the manufacturing process of the solid-state image element according to the first embodiment;

FIG. 4B is a process sectional view showing the manufacturing process of the solid-state image element according to the first embodiment;

FIG. 4C is a process sectional view showing the manufacturing process of the solid-state image element according to the first embodiment;

FIG. 4D is a process sectional view showing the manufacturing process of the solid-state image element according to the first embodiment;

FIG. 5 is a schematic plan view showing the configuration of a solid-state image element according to a second embodiment;

FIG. 6A is a process sectional view showing the manufacturing process of the solid-state image element according to the second embodiment;

FIG. 6B is a process sectional view showing the manufacturing process of the solid-state image element according to the second embodiment;

FIG. 6C is a process sectional view showing the manufacturing process of the solid-state image element according to the second embodiment;

FIG. 6D is a process sectional view showing the manufacturing process of the solid-state image element according to the second embodiment;

FIG. 6E is a process sectional view showing the manufacturing process of the solid-state image element according to the second embodiment;

FIG. 6F is a process sectional view showing the manufacturing process of the solid-state image element according to the second embodiment;

FIG. 6G is a process sectional view showing the manufacturing process of the solid-state image element according to the second embodiment;

FIG. 6H is a process sectional view showing the manufacturing process of the solid-state image element according to the second embodiment;

FIG. 7A is a process sectional view showing the manufacturing process of the solid-state image element according to the second embodiment;

FIG. 7B is a process sectional view showing the manufacturing process of the solid-state image element according to the second embodiment;

FIG. 7C is a process sectional view showing the manufacturing process of the solid-state image element according to the second embodiment;

FIG. 7D is a process sectional view showing the manufacturing process of the solid-state image element according to the second embodiment;

FIG. 7E is a process sectional view showing the manufacturing process of the solid-state image element according to the second embodiment;

FIG. 7F is a process sectional view showing the manufacturing process of the solid-state image element according to the second embodiment;

FIG. 7G is a process sectional view showing the manufacturing process of the solid-state image element according to the second embodiment;

FIG. 7H is a process sectional view showing the manufacturing process of the solid-state image element according to the second embodiment;

FIG. 8 is a schematic plan view showing the configuration of a solid-state image element of the prior art; and

FIG. 9 is a schematic sectional view showing the configuration of the solid-state image element of the prior art.

### DESCRIPTION OF THE EMBODIMENTS

According to the present invention, a solid-state image element includes, a vertical transfer register and a horizontal transfer register and has photoelectric conversion regions two-dimensionally arranged therein, wherein a low-resistance connection electrode connected to the high-concentration impurity region of any one of the photoelectric conversion regions is formed concurrently with a light-shielding film and the connection electrode is grounded on a substrate potential setting electrode. With this configuration, a contact is reliably made in the high-concentration impurity region to stabilize an unstable potential around the high-concentration impurity region, thereby reducing a potential difference. Thus even when cells are reduced in size, it is possible to suppress the occurrence of shading and keep high image quality without increasing manufacturing steps.

The following will describe embodiments of the present invention with reference to the accompanying drawings.

### First Embodiment

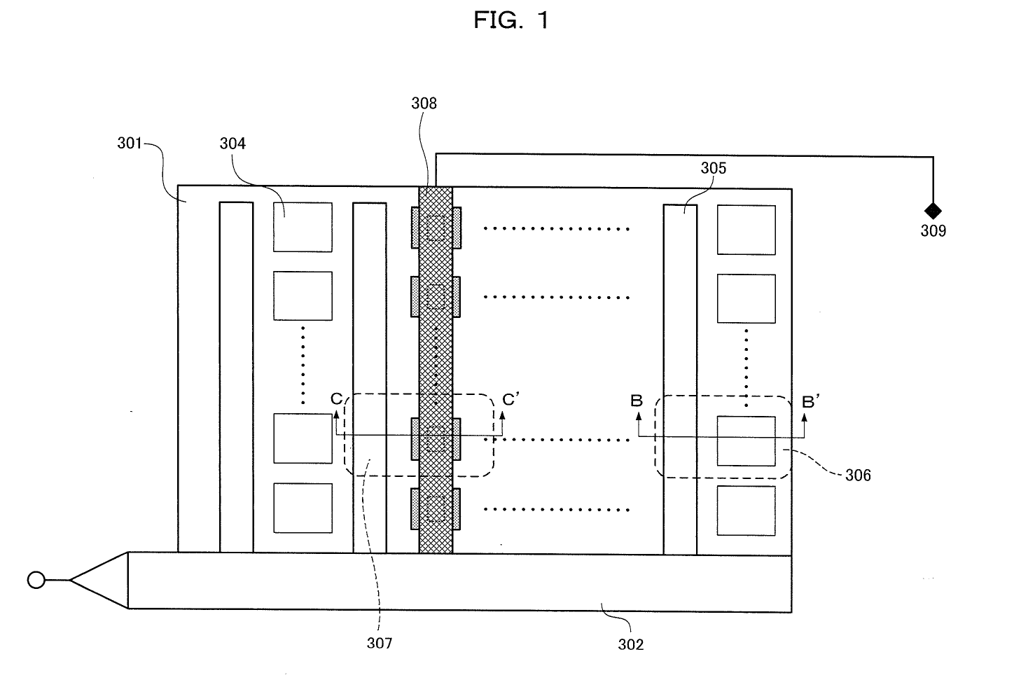

First, referring to FIGS. 1, 2A to 2F, 3A to 3F, and 4A to 4D, a solid-state image element and a solid-state image device of a first embodiment will be described below.

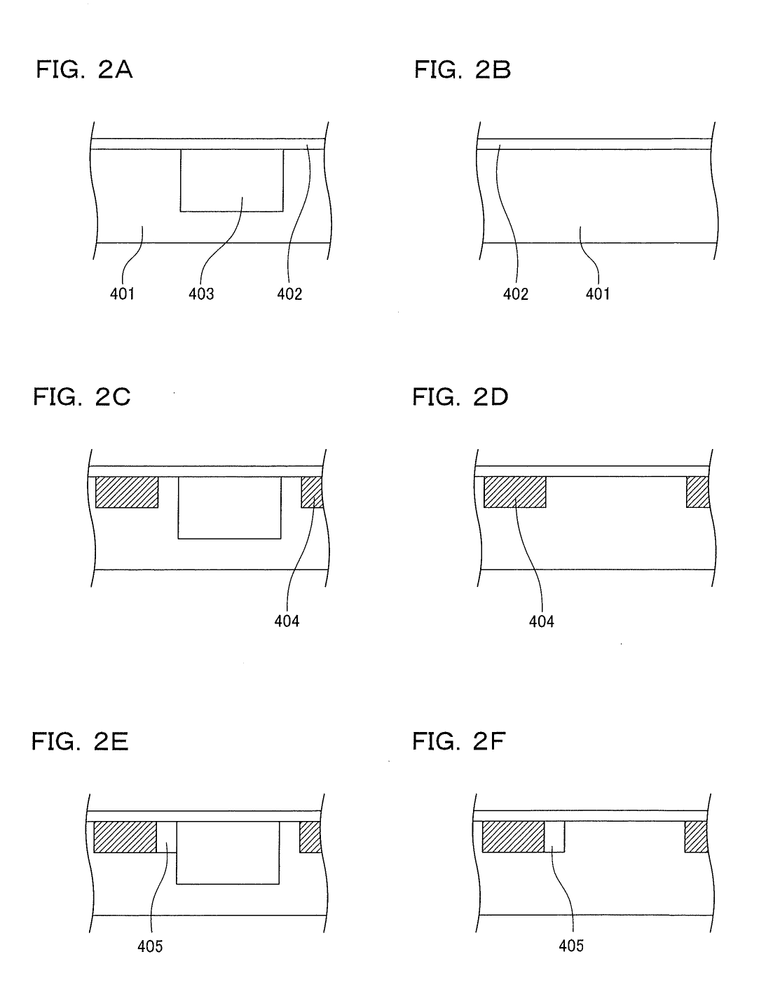

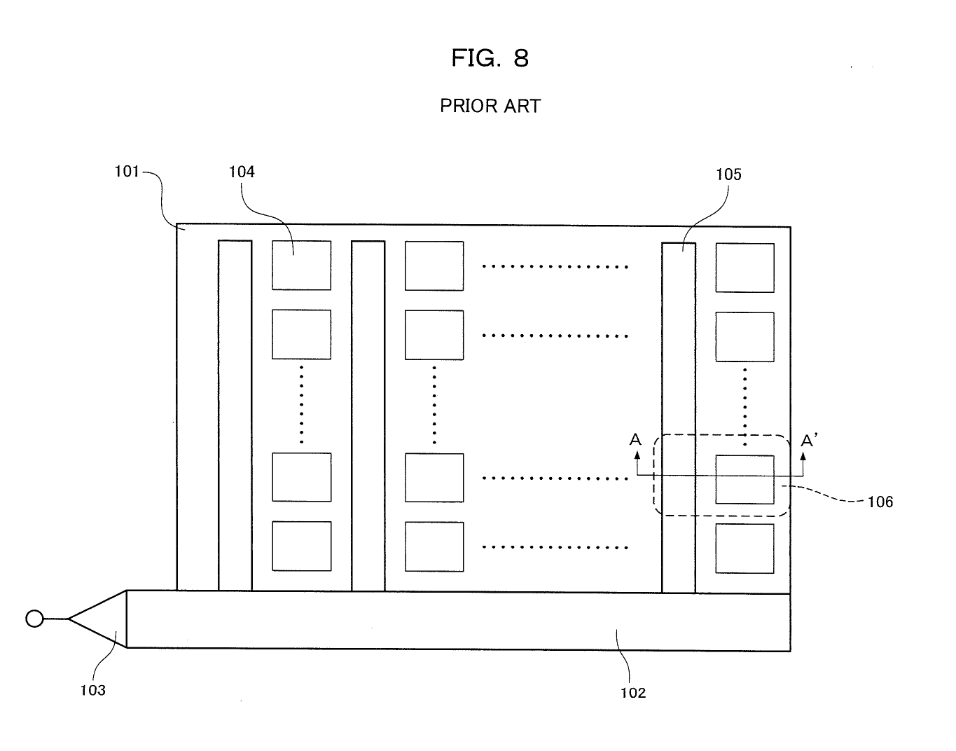

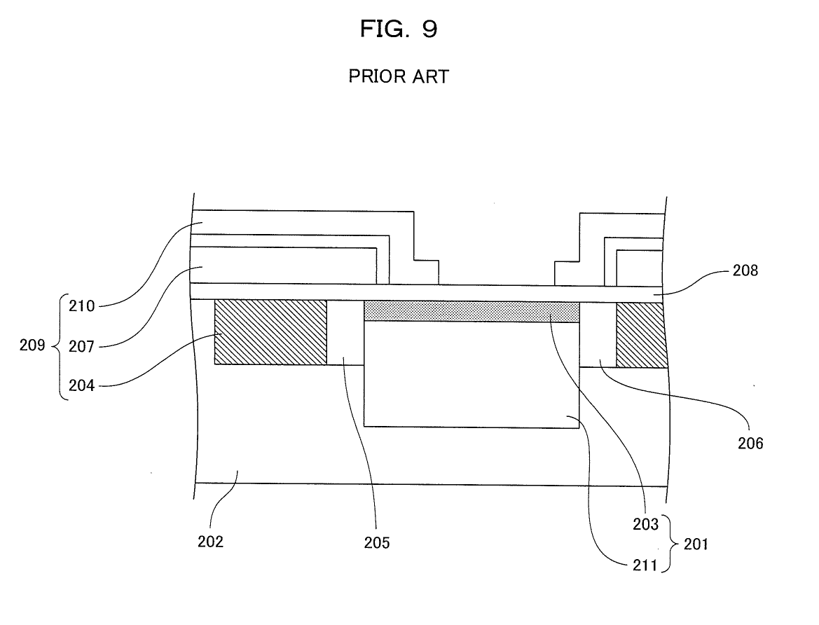

FIG. 1 is a schematic plan view showing the configuration of the solid-state image element according to the first embodiment. The overall configuration of the CCD solid-state image element is similar to, for example, the configurations of FIGS. 8 and 9. The solid-state image element of the first embodiment is different in that a connection electrode 308 is provided in a pixel region 301. The connection electrode 308 connects substrate potential setting pixels 307 for setting a substrate potential and a substrate potential setting electrode 309 that is provided outside the pixel region 301 and is fixed at a ground potential. FIGS. 2A to 2F, 3A to 3F, and 4A to 4D are process sectional views showing the manufacturing process of the solid-state image element according to the first embodiment.

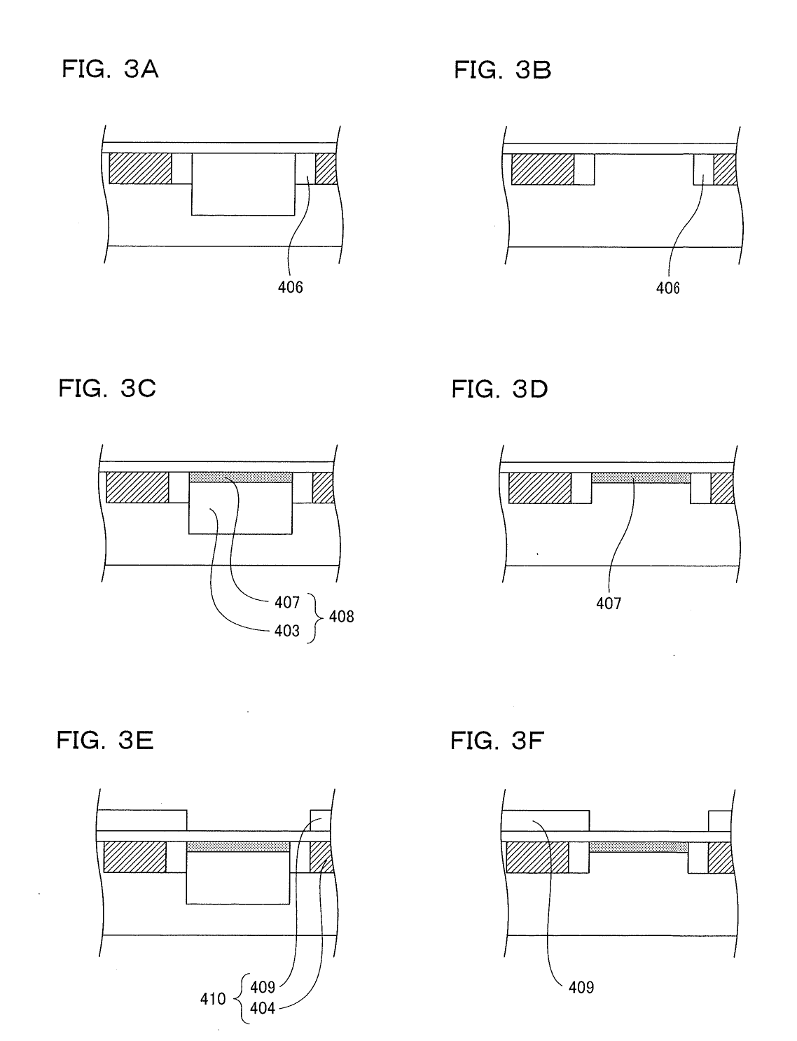

As shown in FIG. 1, the solid-state image element of the first embodiment is configured as follows: first, in the case where a unit pixel 306 is made up of a photoelectric conversion region 304 and a vertical transfer register 305 adjacent to the photoelectric conversion region 304, the unit pixels 306 of any column are replaced with the substrate potential setting pixels 307. Further, the connection electrode 308 connected to a high-concentration P-type impurity region 407 (see FIGS. 3C to 3F) of the substrate potential setting pixel 307 is provided on the high-concentration P-type impurity region 407 (see FIGS. 3C to 3F) of the substrate potential setting pixel 307. Moreover, the connection electrodes 308 on the adjacent substrate potential setting pixels 307 are connected to each other and are extended to an end of the pixel region 301 upstream in the vertical transfer direction, on the opposite side from the formation region of a horizontal transfer register 302. Further, the connection electrodes 308 are connected to the substrate potential setting electrode 309 provided outside the pixel region 301.

Of the high-concentration P-type impurity regions 407 (see FIGS. 3C to 3F) that are connected to one another and are grounded outside the pixel region 301, the unit pixel 306 in a region having an unstable potential is replaced with the substrate potential setting pixel 307, so that the high-concentration P-type impurity region 407 (see FIGS. 3C to 3F) of the region can be grounded to the substrate potential setting electrode 309. By replacing a proper region with the substrate potential setting pixel 307, it is possible to stabilize the potentials of the high-concentration P-type impurity regions 407 (see FIGS. 3C to 3F) in the overall pixel region 301 and reduce a potential difference between the high-concentration P-type impurity regions 407 (see FIGS. 3C to 3F).

It is not always necessary to provide the connection electrode 308 on all of the high-concentration P-type impurity regions 407 (see FIGS. 3C to 3F) of one or more columns. When the unit pixel 306 on the side of the horizontal transfer register 302 is not replaced, it is not necessary to form the connection electrode 308 over the column, so that imaging can be performed on the unit pixel 306 having not been replaced with the substrate potential setting pixel 307.

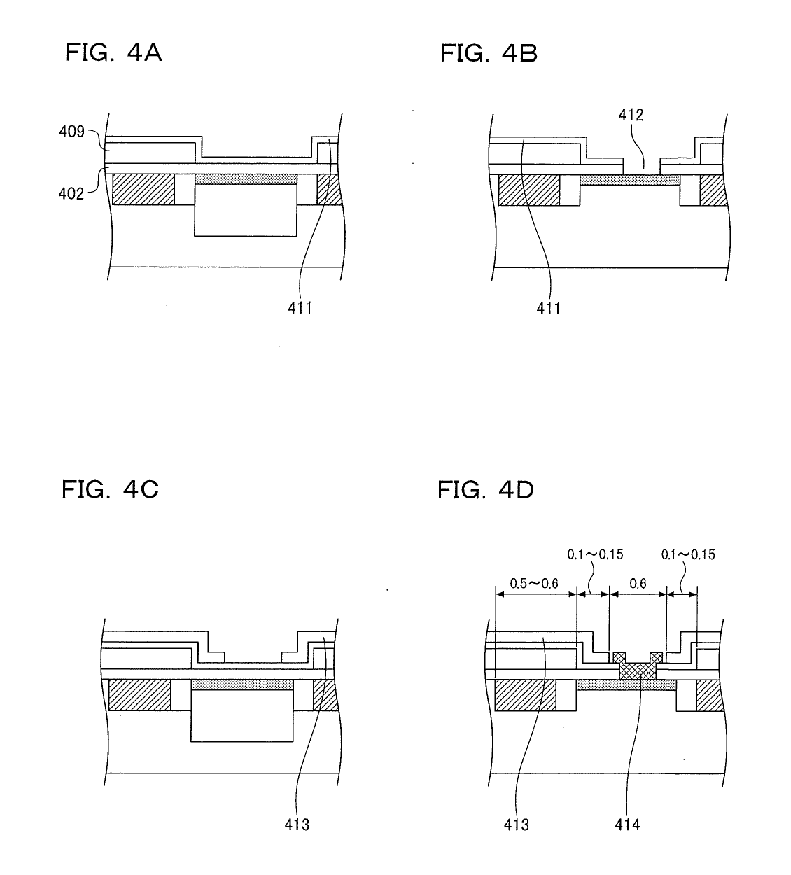

The connection electrode 308 is not directly connected to the substrate potential setting electrode 309, the unit pixels 306 are replaced with the substrate potential setting pixels 307 not in columns but in pixels, the connection electrode 308 is connected to an adjacent light-shielding film 413 (see FIGS. 4C and 4D), and the light-shielding film 413 (see FIGS. 4C and 4D) is connected to the substrate potential setting electrode 309. Thus it is possible to stabilize the potentials of the high-concentration P-type impurity regions 407 (see FIGS. 3C to 3F) of the overall pixel region 301 while optimizing the number of unit pixels 306 to be replaced with the substrate potential setting pixels 307.

Next, referring to FIGS. 2A to 2F, 3A to 3F, and 4A to 4D, the manufacturing method of the present embodiment will be described below along with the detailed configuration of the present embodiment. FIGS. 2A, 2C, 2E, 3A, 3C, 3E, 4A, and 4C are horizontal sectional views of the unit pixel 306 taken along broken line B-B′ of FIG. 1. FIGS. 2B, 2D, 2F, 3B, 3D, 3F, 4B, and 4D are horizontal sectional views of the substrate potential setting pixel 307 taken along broken line C-C′ of FIG. 1. In the explanation of the manufacturing method of the present embodiment, only the unit pixel 306 and the substrate potential setting pixel 307 that are main points of the present embodiment will be described below. The explanation of the manufacturing method of a horizontal charge transfer register 302 and a charge-voltage conversion part is omitted.

First, as shown in FIGS. 2A and 2B, a gate insulating film 402 (e.g., 20 nm) is formed on the surface of a first P-type semiconductor substrate 401 by a thermal oxidation method and the like. The gate insulating film 402 is, for example, an oxide silicon film. On the gate insulating film 402, a photoresist is formed and then is partially removed (not shown) to open a region in which an N-type impurity region 403 described below is formed. In this case, the photoresist is formed such that the N-type impurity region 403 is formed in the unit pixel 306 but is not formed in the substrate potential setting pixel 307. After that, for example, implantation energy is set at 500 keV and a dose is set at 5.0E12/cm². Further, N-type impurities such as arsenic (As) are ion implanted. Thus the N-type impurity region 403 is formed (FIG. 2A) in which a PD (photoelectric conversion region) 408 described below is formed.

Next, the photoresist formed in FIGS. 2A and 2B is completely removed, and then a photoresist is formed again on the gate insulating film 402 as shown in FIGS. 2C and 2D. The photoresist is partially removed (not shown) so as to open regions in which vertical charge transfer regions 404 described below are formed. After that, for example, the implantation energy is set at 200 keV and the dose is set at 4.0E12/cm². Further, N-type impurities such as arsenic (As) are ion implanted. Thus the vertical charge transfer regions 404 are formed in which vertical transfer registers (VCCD) described below are formed. It is not always necessary to form the vertical charge transfer regions 404 in the substrate potential setting pixel 307. When all the pixels in a column are not replaced with the substrate potential setting pixels 307, it is necessary to form the vertical charge transfer regions 404 also in the substrate potential setting pixel 307 to transfer the signal charge of the unit pixel 306.

Next, the photoresist formed in FIGS. 2C and 2D is completely removed, and then a photoresist is formed again on the gate insulating film 402 as shown in FIGS. 2E and 2F. The photoresist is partially removed (not shown) so as to open regions in which reading parts 405 described below are formed. After that, for example, the implantation energy is set at 100 keV and the dose is set at 5.0E12/cm². Further, P-type impurities such as boron (B) are ion implanted. Thus the reading parts 405 are formed.

Next, the photoresist formed in FIGS. 2E and 2F is completely removed, and then a photoresist is formed again on the gate insulating film 402 as shown in FIGS. 3A and 3B. The photoresist is partially removed (not shown) so as to open regions in which element isolation parts 406 described below are formed. After that, for example, the implantation energy is set at 100 keV and the dose is set at 1.0E13/cm². Further, P-type impurities such as boron (B) are ion implanted. Thus the element isolation parts 406 are formed.

Next, the photoresist formed in FIGS. 3A and 3B is completely removed, and then a photoresist is formed again on the gate insulating film 402 as shown in FIGS. 3C and 3D. The photoresist is partially removed (not shown) so as to open regions in which the high-concentration P-type impurity regions 407 described below are formed. After that, for example, the implantation energy is set at 10 keV and the dose is set at 1.0E14/cm². Further, P-type impurities such as boron (B) are ion implanted. Thus the high-concentration P-type impurity regions 407 are formed. The PD (photoelectric conversion region) 408 is made up of the high-concentration P-type impurity region 407 and the foregoing N-type impurity region 403. In this case, the high-concentration P-type impurity region 407 of the substrate potential setting pixel 307 is deeply formed in the vertical direction of the substrate. Thus it is possible to efficiently obtain the effect of grounding and further stabilize the potential of the high-concentration P-type impurity region 407.

Next, the photoresist formed in FIGS. 3C and 3D is completely removed, and then polycrystalline silicon (e.g., 300 nm) is formed on the gate insulating film 402 by chemical vapor deposition (CVD) method and the like as shown in FIGS. 3E and 3F. Further, a photoresist (not shown) is formed on the polycrystalline silicon and then is removed outside regions in which transfer electrodes 409 described below are formed. The polycrystalline silicon is removed by, for example, reactive ion etching (RIE) with the photoresist serving as a mask, so that the transfer electrodes 409 are formed. A vertical transfer register (VCCD) 410 is made up of the transfer electrode 409 and the foregoing vertical charge transfer region 404. In this case, the transfer electrode 409 in the substrate potential setting pixel 307 is smaller in width than the transfer electrode 409 in the unit pixel 306 such that the transfer electrode 409 in the substrate potential setting pixel 307 has an end located near the high-concentration P-type impurity region 407 and the end is shortened to the opposite side from the high-concentration P-type impurity region 407. Thus an opening between the transfer electrodes 409 is increased and a connection electrode 414 described below can be easily formed. Moreover, a vertical transfer signal is not applied to the substrate potential setting pixel 307 in which photoelectric conversion is not performed, thereby preventing vertical transfer of unidentified noise.

Next, the photoresist formed in FIGS. 3E and 3F is completely removed, and then an interlayer insulating film 411 (for example, the interlayer insulating film is an oxide silicon film) is formed on the gate insulating film 402 and the transfer electrodes 409 by the CVD method and the like as shown in FIGS. 4A and 4B. After that, a photoresist is formed again and then is partially removed (not shown) so as to open a region in which a contact hole 412 described below is formed in the substrate potential setting pixel 307 to connect the high-concentration P-type impurity region 407 and a connection electrode 414 described below. The gate insulating film 402 is removed by, for example, RIE with the photoresist serving as a mask, so that the contact hole 412 is formed (FIG. 4B).

Next, the photoresist formed in FIGS. 4A and 4B is completely removed, and then a tungsten film is formed by the CVD method and the like as shown in FIGS. 4C and 4D. After that, a photoresist is formed again and then is removed outside regions in which the light-shielding films 413 described below and the connection electrode 414 are formed. The tungsten film is removed by, for example, RIE with the photoresist serving as a mask, so that the light-shielding films 413 and the connection electrode 414 are simultaneously formed. The unit pixel 306 and the substrate potential setting pixel 307 of the present embodiment are completed thus.

The typical dimensions are determined as follows: the opening of the light-shielding film 413 forms the connection electrode 414 and has a width of about 0.6 μm, and a width from the transfer electrode 409 to the opening of the light-shielding film 413 is about 0.1 μm to 0.15 μm. Further, the transfer electrode 409 for vertical transfer has a width of about 0.5 μm to 0.6 μm. The width reduced as previously mentioned facilitates the formation of the connection electrode 414.

The connection electrode 414 is connected to the substrate potential setting electrode 309 (see FIG. 1), on the end of the pixel region 301 formed over columns in which the substrate potential setting pixels 307 are formed as shown in FIG. 1. When the pixels in all columns are not replaced with the substrate potential setting pixels 307, the connection electrode 414 may be formed between the end connected to the substrate potential setting electrode 309 and the substrate potential setting pixels 309 provided at the farthest location.

As previously mentioned, the high-concentration P-type impurity region 407 and the substrate potential setting electrode 309 are connected to each other via the low-resistance connection electrode 414 formed concurrently with the light-shielding film 413, so that the holes of electron-hole pairs generated by incident light in the PD (photoelectric conversion region) 408 are discharged through the low-resistance connection electrode 414 (the electrons are stored as signal charge in the PD (photoelectric conversion region) 408). Thus it is possible to suppress a potential difference between the high-concentration P-type impurity regions 407 in the pixel region 301. Particularly, at the center of the pixel region 301 (see FIG. 1), the high-concentration P-type impurity region 407 is far from the ground of the high-concentration P-type impurity region 407 and has an unstable potential. Thus the high-concentration P-type impurity regions 407 around the high-concentration P-type impurity region 407 located at the center are directly connected to the substrate potential setting electrode 309 (see FIG. 1) via the connection electrodes 414, thereby stabilizing the potentials of the high-concentration P-type impurity regions 407 over the pixel region 301 (see FIG. 1). Thus it is possible to obtain a high-quality image with no shading while achieving uniformity over the image.

Since the substrate potential setting pixels 307 do not have the PDs (photoelectric conversion region) 408, the regions of the substrate potential setting pixels 307 are missing in an image. However, the missing regions may be compensated by a signal processing circuit. Currently, resolutions have been increased as cells have been reduced in size, so that the compensation by the signal processing circuit hardly reduces image quality. In other words, the number of substrate potential setting pixels 307 to be formed is adjusted in consideration of a balance of the potential stabilization of the high-concentration P-type impurity regions 407 in the substrate potential setting pixels 307 and missing imaging pixels. For example, in a pixel array of about 4000 columns, the substrate potential setting pixels 307 provided only in several columns can achieve a sufficient effect. The missing regions of the several columns hardly reduce image quality.

It is not always necessary to form the connection electrodes 414 in columns. The connection electrodes 414 may be formed only in regions connectable to the adjacent light-shielding films 413. In this case, the substrate potential setting pixels 307 can be provided in pixels and thus it is possible to more efficiently stabilize potentials and minimize missing regions.

### Second Embodiment

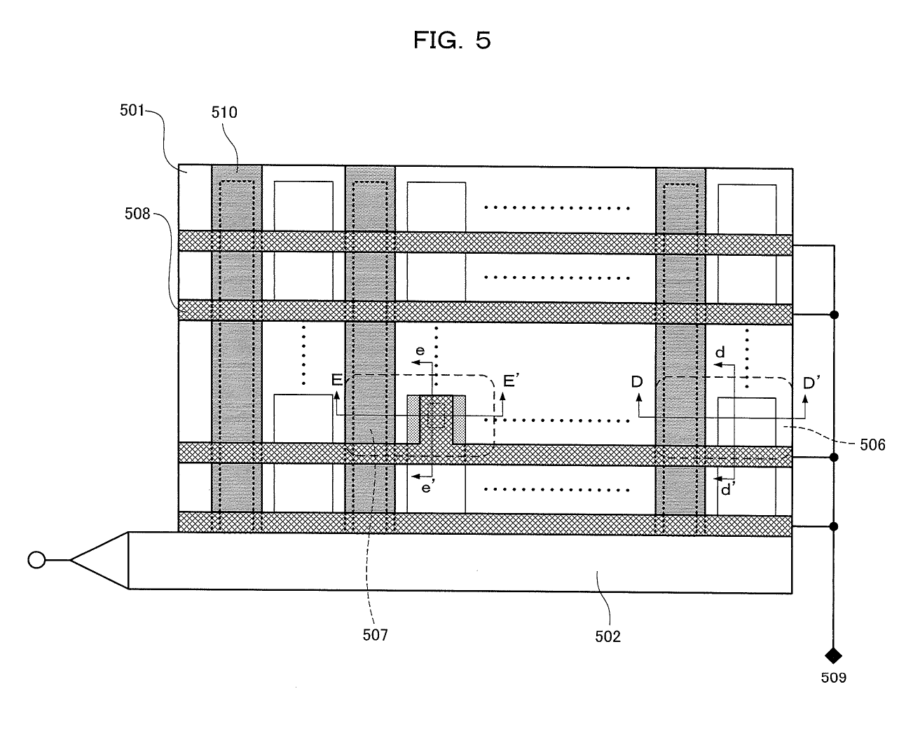

Referring to FIGS. 5, 6A to 6H, and 7A to 7H, the following will describe a solid-state image element and a solid-state image device according to a second embodiment.

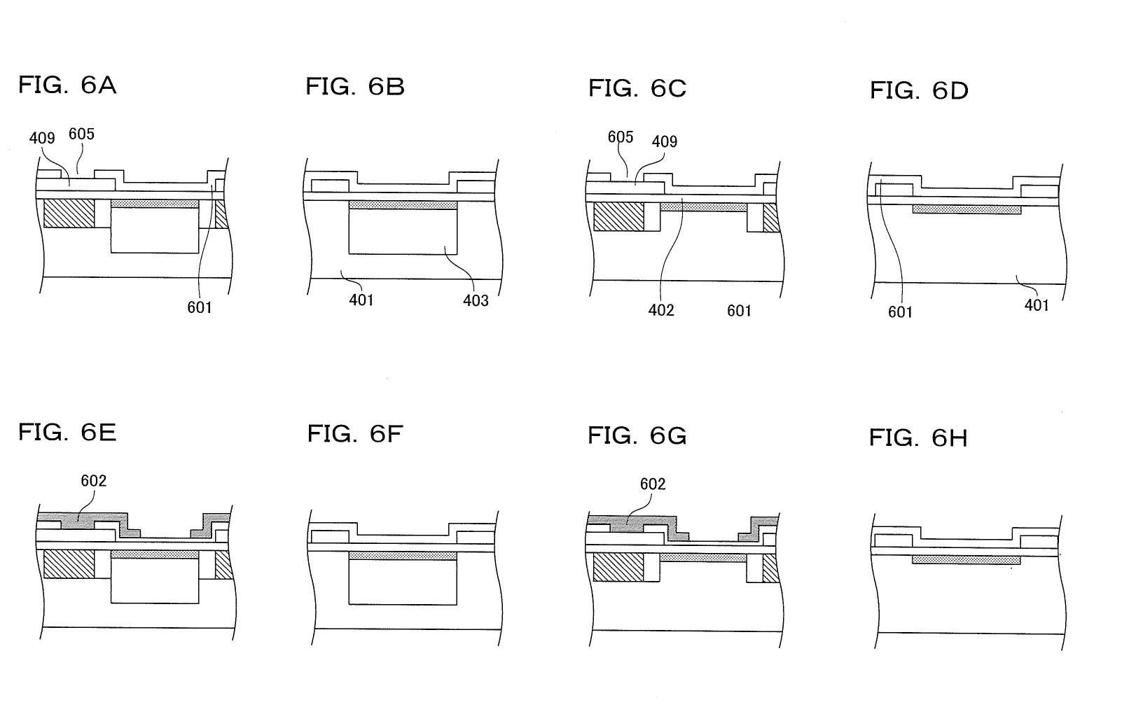

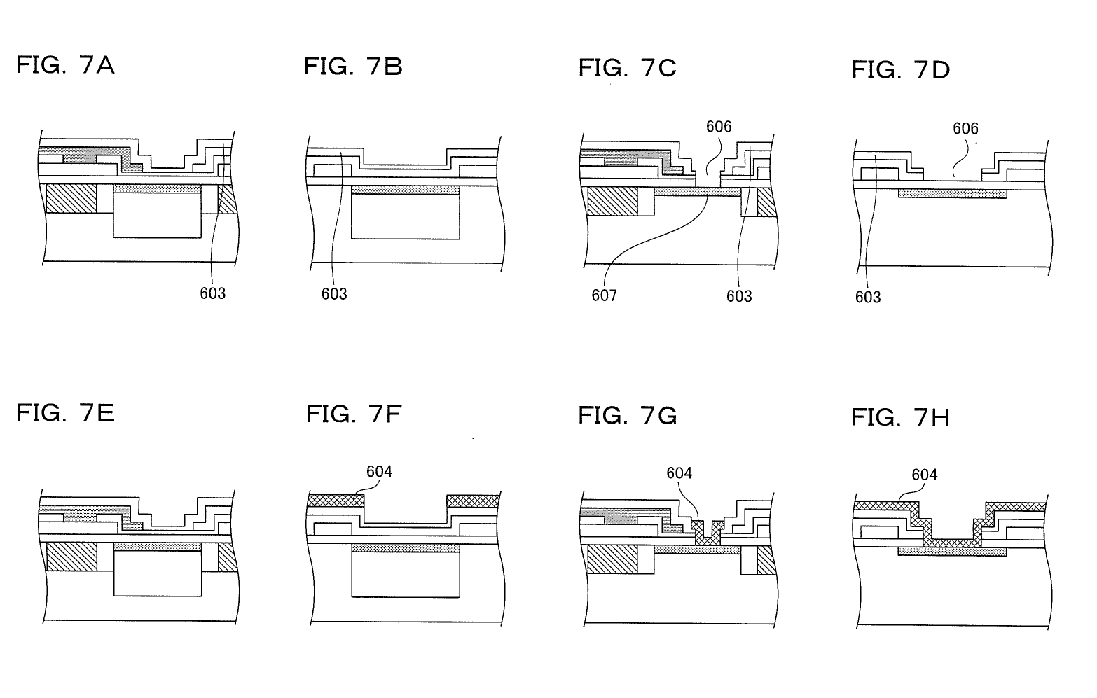

FIG. 5 is a schematic plan view showing the configuration of the solid-state image element according to the second embodiment. The overall configuration of the CCD solid-state image element is similar to, for example, the configuration of FIG. 1. The solid-state image element of the second embodiment is different in that the solid-state image element has first light-shielding films 510 and second light-shielding films 508 and has a shunt wiring structure in which a voltage is applied to transfer electrodes 409 (see FIGS. 6A to 6H) through the first light-shielding films 510, and the second light-shielding films 508 are used in a pixel region 501 as connection electrodes connecting substrate potential setting pixels 507 for setting a substrate potential and a substrate potential setting electrode 509 provided outside the pixel region 501. FIGS. 6A to 6H and 7A to 7H are process sectional views showing the manufacturing process of the solid-state image element of the second embodiment.

As shown in FIG. 5, the solid-state image element of the second embodiment has a shunt wiring structure in which the second light-shielding films 508 are extended and connected to high-concentration P-type impurity regions 607 (see FIG. 7C) of the substrate potential setting pixels 507 and the second light-shielding films 508 are connected to the substrate potential setting electrode 509.

By replacing a unit pixel 506 in a region having an unstable potential with the substrate potential setting pixel 507, a high-concentration P-type impurity region 607 of the region can be grounded to the substrate potential setting electrode 509 through the second light-shielding film 508. By replacing a proper region with the substrate potential setting pixel 507, it is possible to stabilize the potentials of the high-concentration P-type impurity regions 607 of the overall pixel region 501.

In the manufacturing method of the present embodiment, steps until the transfer electrodes 409 are formed are similar to the steps of the first embodiment (FIGS. 2A to 2F and 3A to 3F). The following will describe steps after the transfer electrodes 409 are formed.

FIGS. 6A, 6E, 7A, and 7E are horizontal sectional views of the unit pixel 506 taken along broken line D-D′ of FIG. 5 after the transfer electrodes 409 are formed. FIGS. 6B, 6F, 7B, and 7F are vertical sectional views of the unit pixel 506 taken along broken line d-d′ of FIG. 5 after the transfer electrodes 409 are formed. FIGS. 6C, 6G, 7C, and 7G are horizontal sectional views of the substrate potential setting pixel 507 taken along broken line E-E′ of FIG. 5 after the transfer electrodes 409 are formed. FIGS. 6D, 6H, 7D, and 7H are vertical sectional views of the substrate potential setting pixel 507 taken along broken line e-e′ of FIG. 5 after the transfer electrodes 409 are formed.

After the transfer electrodes 409 are formed, as shown in FIGS. 6A to 6D, a first interlayer insulating film 601 (for example, the interlayer insulating film is an oxide silicon film) is formed on a gate insulating film 402 and the transfer electrodes 409 by CVD method and the like. After that, a photoresist is formed and then is partially removed (not shown) so as to open a region in which a first contact hole 605 described below is formed to connect the transfer electrode 409 and a first light-shielding film 602 described below. The gate insulating film 402 and the first interlayer insulating film 601 are removed by, for example, RIE with the photoresist serving as a mask, so that the first contact hole 605 is formed.

Next, the photoresist formed in FIGS. 6A to 6D is completely removed, and then a tungsten film is formed as shown in FIGS. 6E to 6H. After that, a photoresist is formed again and then is removed outside a region in which the first light-shielding film 602 described below is formed. The tungsten film is removed by, for example, RIE with the photoresist serving as a mask, so that the first light-shielding film 602 is formed.

Next, the photoresist formed in FIGS. 6E to 6H is completely removed, and then a second interlayer insulating film 603 (for example, the interlayer insulating film is an oxide silicon film) is formed by the CVD method and the like as shown in FIGS. 7A to 7D. After that, a photoresist is formed again and then is partially removed (not shown) to open a region in which a second contact hole 606 described below is formed to connect the high-concentration P-type impurity region 607 and a second light-shielding film 604 described below in the substrate potential setting pixel 507. The gate insulating film 402, the first interlayer insulating film 601, and the second interlayer insulating film 603 are removed by, for example, RIE with the photoresist serving as a mask, so that the second contact hole 606 is formed.

Next, the photoresist formed in FIGS. 7A to 7D is completely removed, and then a tungsten film is formed by the CVD method and the like as shown in FIGS. 7E to 7H. After that, a photoresist is formed again and then is removed outside a region in which the second light-shielding film 604 described below is formed. The tungsten film is removed by, for example, RIE with the photoresist serving as a mask, so that the second light-shielding film 604 is formed. The unit pixel 506 and the substrate potential setting pixel 507 of the present embodiment are completed thus.

In the substrate potential setting pixel 507, the second light-shielding film 604 is extended so as to be connected to the high-concentration P-type impurity region 607. Further, as shown in FIG. 5 (the second light-shielding films 508 in FIG. 5), the second light-shielding films 604 are connected to the substrate potential setting electrode 509 provided outside the pixel region 501, and act as connection electrodes in the first embodiment.

As previously mentioned, also in the present embodiment, the high-concentration P-type impurity region 607 and the substrate potential setting electrode 509 are connected to each other via the low-resistance second light-shielding film 604, so that the holes of electron-hole pairs generated by incident light in a PD (photoelectric conversion region) are discharged from the second light-shielding film 508 that is a low-resistance connection electrode (the electrons are stored as signal charge in the PD (photoelectric conversion region)). Thus it is possible to suppress a potential difference between the high-concentration P-type impurity regions 607 in the pixel region 501. Therefore, it is possible to obtain a high-quality image with no shading while achieving uniformity over the image.

In the first embodiment, the light-shielding film 413 and the connection electrode 414 are simultaneously formed, so that the substrate potential setting pixels provided in columns cause missing pixels in stripes, whereas in the present embodiment, the second light-shielding film 604 is used as a connection electrode, so that regions with missing pixels can be reduced by replacing any unit pixel with the substrate potential setting pixel 507.

Also in the present embodiment, the regions of the substrate potential setting pixels 507 are missing in an image as in the first embodiment. The missing regions may be compensated by a signal processing circuit. As previously mentioned, any unit pixel can be replaced with the substrate potential setting pixel 507. By optimizing the unit pixel 506 to be replaced with the substrate potential setting pixel 507, it is possible to suppress the degradation of the pixel while stabilizing the potential of the high-concentration P-type impurity region 607.

The potential of the high-concentration P-type impurity region 607 is typically set by making contact with a peripheral part of the pixel region. Thus by forming the substrate potential setting pixel 507 at the center of the pixel region 501, that is, at a location away from the peripheral part serving as a ground, it is possible to efficiently suppress a potential difference. Typically, the high-concentration P-type impurity region 607 is not formed in a horizontal charge transfer register. Thus by forming the substrate potential setting pixel 507 between the Center of the pixel region 501 and a horizontal transfer register 502, it is possible to more efficiently suppress a potential difference.

The foregoing explanation described an example in which the first light-shielding films 510 and the second light-shielding films 508 form grid-like light-shielding films. The second light-shielding films 508 are formed also on the first light-shielding films 510, so that the high-concentration P-type impurity regions 607 can be more easily connected to the second light-shielding films 508.

As in the first embodiment, the high-concentration P-type impurity region 607 of the substrate potential setting pixel 507 is deeply formed, so that the effect of grounding can be efficiently obtained to further stabilize the potential of the high-concentration P-type impurity region 607.

Further, the first light-shielding film 510 in the substrate potential setting pixel 507 is smaller in width than the first light-shielding film 510 in the unit pixel 506 such that the first light-shielding film 510 in the substrate potential setting pixel 507 has an end located near the high-concentration P-type impurity region 607 and the end is shortened to the opposite side from the high-concentration P-type impurity region 607. Thus an opening between the first light-shielding films 510 is increased and the second light-shielding films 508 can be easily formed. Moreover, a vertical transfer signal is not applied to the substrate potential setting pixel 507 in which photoelectric conversion is not performed, thereby preventing vertical transfer of unidentified noise.

The same effect as the first and second embodiments can be obtained also by providing through holes from the underside of the semiconductor substrate to connect the high-concentration P-type impurity regions of the substrate potential setting pixels and through electrodes, thereby suppressing the occurrence of shading.

What is claimed is:

1. A solid-state image element for vertically and horizontally transferring a charge signal photoelectrically converted in each pixel,
the solid-state image element comprising:
a vertical transfer register for vertically transferring the charge signal in response to a control signal inputted to a first transfer electrode;
a horizontal transfer register for horizontally transferring the charge signal in response to a control signal inputted to a second transfer electrode;
a plurality of first light-shielding films formed at least on the vertical transfer register;
at least one substrate potential setting pixel region having a high-concentration impurity region at least in a surface layer of the substrate potential setting pixel region;
a substrate potential setting electrode fixed at a ground potential;
a connection electrode for connecting the high-concentration impurity region of the substrate potential setting pixel region and the substrate potential setting electrode; and
photoelectric conversion regions two-dimensionally arranged in regions other than the substrate potential setting pixel region so as to be adjacent to the vertical transfer register via the first transfer electrode, the photoelectric conversion region being made up of a high-concentration impurity region and an impurity region for storing signal charge.

2. The solid-state image element according to claim 1, wherein the substrate potential setting pixel regions are formed in at least one column.

3. The solid-state image element according to claim 2, wherein the connection electrode is connected to all of the substrate potential setting pixel regions of the column.

4. The solid-state image element according to claim 1, wherein the connection electrode is a same film as the first light-shielding film.

5. The solid-state image element according to claim 1, wherein the high-concentration impurity region formed in the substrate potential setting pixel region is deeper than the high-concentration impurity region formed in the photoelectric conversion region.

6. The solid-state image element according to claim 1, wherein the first transfer electrode in a region adjacent to the substrate potential setting pixel region is smaller in width than the first transfer electrode in a region adjacent to the photoelectric conversion region and the second transfer electrode in a region adjacent to the substrate potential setting pixel region is smaller in width than the second transfer electrode in a region adjacent to the photoelectric conversion region.

7. The solid-state image element according to claim 1, wherein the substrate potential setting pixel region is provided at least around a center of the solid-state image element.

8. The solid-state image element according to claim 1, wherein the substrate potential setting pixel region is provided at least between a center of the solid-state image element and the horizontal charge transfer register.

9. The solid-state image element according to claim 1, wherein the first light-shielding film is extended to serve as the connection electrode.

10. A solid-state image element having a shunt wiring structure for vertically and horizontally transferring a charge signal photoelectrically converted in each pixel,
the solid-state image element comprising:
a vertical transfer register for vertically transferring the charge signal in response to a control signal inputted to a first transfer electrode;
a horizontal transfer register for horizontally transferring the charge signal in response to a control signal inputted to a second transfer electrode;
a plurality of first light-shielding films formed at least on the vertical transfer register;
a substrate potential setting electrode fixed at a ground potential;
a plurality of second light-shielding films horizontally formed in stripes and connected to the substrate potential setting electrode;
at least one substrate potential setting pixel region having a high-concentration impurity region at least in a surface layer of the substrate potential setting pixel region;
a connection electrode for connecting the high-concentration impurity region of the substrate potential setting pixel region and the second light-shielding film; and
photoelectric conversion regions two-dimensionally arranged in regions other than the substrate potential setting pixel region so as to be adjacent to the vertical transfer register via the first transfer electrode, the photoelectric conversion region being made up of a high-concentration impurity region and an impurity region for storing signal charge.

11. The solid-state image element according to claim 10, wherein the second light-shielding films are formed in a lattice pattern also on the first light-shielding films.

12. The solid-state image element according to claim 10, wherein the connection electrode is a same film as the first light-shielding film.

13. The solid-state image element according to claim 10, wherein the connection electrode is a same film as the second light-shielding film.

14. The solid-state image element according to claim 10, wherein the high-concentration impurity region formed in the substrate potential setting pixel region is deeper than the high-concentration impurity region formed in the photoelectric conversion region.

15. The solid-state image element according to claim 10, wherein the first transfer electrode in a region adjacent to the substrate potential setting pixel region is smaller in width than the first transfer electrode in a region adjacent to the photoelectric conversion region and the second transfer electrode in a region adjacent to the substrate potential setting pixel region is smaller in width than the second transfer electrode in a region adjacent to the photoelectric conversion region.

16. The solid-state image element according to claim 10, wherein the substrate potential setting pixel region is provided at least around a center of the solid-state image element.

17. The solid-state image element according to claim 10, wherein the substrate potential setting pixel region is provided at least between a center of the solid-state image element and the horizontal charge transfer register.

18. A solid-state image device comprising the solid-state image element according to claim 1 and a signal processing circuit for compensating for a missing pixel in the substrate potential setting pixel region.
